(19) United States
(12) Patent Application Publication
(10) Pub. No.: US 2025/0036822 A1
(43) Pub. Date: Jan. 30, 2025

(54) Intelligent Resilience Urban-Rural Evaluation System and Method

(71) Applicant: YUNNAN DESIGN INSTITUTE GROUP CO., LTD, Kunming, Yunnan (CN)

(72) Inventors: Yu ZHOU, Kunming, Yunnan (CN); Guo CHEN, Kunming, Yunnan (CN); Ji LIANG; Hongxu DENG, Kunming, Yunnan (CN)

(21) Appl. No.: 18/548,879

(22) PCT Filed: Feb. 6, 2023
(86) PCT No.: PCT/CN2023/074540

§ 371 Date: Sep. 1, 2023

(30) Foreign Application Priority Data
Dec. 5, 2022 (CN) 202211587924.7

(51) Int. Cl. G06F 30/13

(52) U.S. Cl. CPC G06F 30/13

(57) ABSTRACT

The present invention provides an intelligent resilience urban-rural evaluation system and a method thereof. The system includes: a data acquisition module, a data processing module, a model building module and an evaluation calculation module. Through the study of influence of earthquake motion time history on reliability and safety of building structures, reliability evaluation and health monitoring of complex building structure systems are realized by using super-computing and storage capabilities of cloud computing.

### CROSS-REFERENCE TO RELATED APPLICATION

This application is a national phase entry under 35 U.S.C. § 371 of International Application No. PCT/CN2023/074540, filed on Feb. 6, 2023, which claims priority to Chinese Patent Application No. 202211587924.7 filed on Dec. 5, 2022, the entire contents of all of which are incorporated herein by reference.

### TECHNICAL FIELD

The present invention relates to a technical field of urban-rural resilience evaluation, in particular to an intelligent resilience urban-rural evaluation system and a method thereof.

### DESCRIPTION OF THE RELATED ART

Resilience cities refer to cities that can resist disasters, reduce losses, and recover quickly from disasters by virtue of their own capabilities. They emphasize that the cities have the capabilities to predict, prevent, respond to, and recover from shocks and pressures when they encounter them. According to essence of this theory, reliability and safety of building structures in urban construction are quantitative expression for showing strength of our capability to resist external disasters, when we encounter them.

At present, most of the evaluation research on urban resilience focus on building the evaluation system of the entire urban system. For example, Chinese patent publication CN115018321A discloses a flexibly configuring and intelligent evaluation system and a method thereof for urban resilience, which generate a matching evaluation model and a matching evaluation index set with regard to basic information of the city, and continuously improve accuracy and adaptability of an evaluation and prediction module through the study and comparison of cases in a resilience evaluation case library. The evaluation and prediction module is constantly optimizing the model of the evaluation system and the evaluation index library when evaluating the urban resilience, thereby automatically iteratively updating the system. However, it does not involve in a specific aspect, such as the evaluation of building structures, and cannot reflect the reliability and safety issues of building structures in resilient urban and rural areas that are most relevant to our safety. Therefore, how to design an intelligent resilience urban-rural evaluation system and a method thereof for the building structures is an urgent technical problem to be solved.

### SUMMARY

In view of this, the present invention proposes an intelligent resilience urban-rural evaluation system and a method thereof to solve the problem that the existing resilience urban-rural evaluation cannot reflect the reliability of the building structures.

The technical solution of the present invention is achieved in the following way: in an aspect, the present invention provides an intelligent resilience urban-rural evaluation system, wherein the system comprises a data acquisition module, a data processing module, a model building module and an evaluation calculation module;
wherein the data acquisition module is electrically connected to the evaluation calculation module, and is used to acquire data information of actual earthquake motion time history, and to send the data information of actual earthquake motion time history to the evaluation calculation module;
the data processing module is electrically connected to the model building module, and is used to process data of the building structures and send the processed data to the model building module;
the model building module is electrically connected to the evaluation calculation module, and is used to build a reliability model of the building structures according to the processed data; and

The evaluation calculation module is used to input the data information of actual earthquake motion time history into the reliability model of the building structures to obtain and display evaluation results for intelligent resilience urban and rural areas.

On the basis of the above technical solution, preferably, the data information of actual earthquake motion time history comprises information of earthquake motion acceleration and duration, and the data information of actual earthquake motion time history is determined by an earthquake wave selection method, and is outputted in real time according to occurrence of actual earthquakes.

On the basis of the above technical solution, preferably, the data processing module decomposes functions and performances of the building structures based on a function-performance analysis method, and determines key characteristics and key performance indicators.

On the basis of the above technical solution, preferably, the model building module is used to build a three-dimensional physical twin model of the building structures which comprises a frame structure, a frame shear structure, a shear wall structure, a steel structure, a high-rise structure, a multi-storey structure and a masonry structure.

On the basis of the above technical solution, preferably, the evaluation calculation module is used to receive in real time the data information of actual earthquake motion time history that is occurring, convert it into a finite element model of YJK calculation for cloud computing, and output data of safety displacement angles and weak layers of the structures, map it to the urban-rural physical twin model through visual information, and then automatically generate the evaluation results according to national regulations and emergency evaluation standards.

In another aspect, the present invention provides an intelligent resilience urban-rural evaluation method as used in the intelligent resilient urban-rural evaluation system as described above. It comprises the following steps:
S1. building a three-dimensional physical twin model of the building structures which comprises a frame structure, a frame-shear structure, a shear wall structure, a steel structure, a high-rise structure, a multi-storey structure, and a masonry structure;
S2. inputting the data information of actual earthquake motion time history, calculating and outputting the displacement angles between layers of the building structures and the weak layers of the building structures in the YJK resilience dynamic motion time history, and obtain evaluation indicators of the urban-rural resilience; and
S3. superimposing the evaluation indicators of the urban-rural resilience with data from a urban-rural physical model, and transmitting them to a visualization system and an evaluation system, and finally generating three results that it can be used, discontinued, and suspended.

On the basis of the above technical solution, preferably, the urban-rural physical model comprises a urban-rural built model and data for updating urban and rural areas.

Compared with the prior art, the intelligent resilience urban-rural evaluation system and the method of the present invention have the following beneficial effects:
(1) By studying the influence of earthquake motion time history on the reliability and safety of the building structures, and using the super-computing and storage capabilities of cloud computing, the reliability evaluation and health monitoring of complex building structure systems are realized;
(2) By establishing the prefabricated building structures and seismic reduction/isolation structure model in the finite element analysis software, and taking into comprehensive consideration of the structural characteristics, load and effect characteristics, and selecting the appropriate number of grids and the degree of grid density of each part for the grid division, the amount of calculation shall be reduced as much as possible while ensuring sufficient accuracy;
(3) Based on the research on health monitoring technology of the building structures, a health monitoring platform of the building structures, including sensor optimization deployment algorithm, health state identification algorithm, and structural safety and economic evaluation criterion algorithm based on a confident reliability theory, is formed.

### BRIEF DESCRIPTION OF THE DRAWINGS

In order to more clearly illustrate the technical solutions in the embodiments of the present invention or the prior art, a brief introduction about the drawings that need to be used in the description of the embodiments or the prior art will be made out in the following. Obviously, the accompanying drawings in the following description are only a part of all the embodiments of the present invention. Those skilled in the art can also obtain other drawings based on these drawings without any creative work.

FIG. 1 is a block diagram of an intelligent resilience urban-rural evaluation system of the present invention; and

FIG. 2 is a flow chart of an intelligent resilience urban-rural evaluation method of the present invention.

### DETAILED DESCRIPTION OF EXEMPLARY EMBODIMENTS

The following will clearly and completely describe the technical solutions in the embodiments of the present invention in conjunction with the embodiments of the present invention. Obviously, the described embodiments are only part of the embodiments of the present invention, not all of them. Based on the implementation in the present invention, all other implementation obtained by the ordinary skilled person in the art without making creative efforts belong to the scope of protection of the present invention.

### First Embodiment

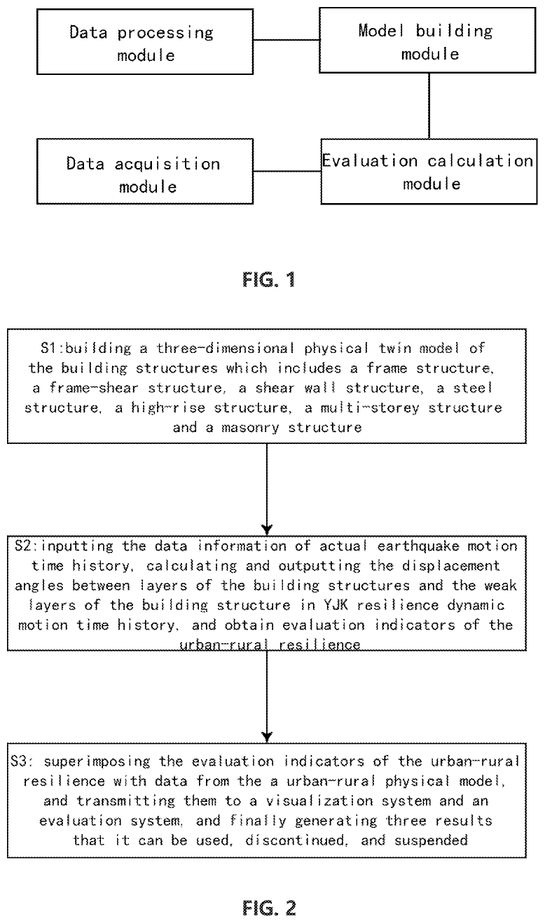

As shown in FIG. 1, an intelligent resilience urban-rural evaluation system of the present invention is provided herein. Specifically, the system includes a data acquisition module, a data processing module, a model building module and an evaluation calculation module.

The data acquisition module is electrically connected to the evaluation calculation module, and is used to acquire data information of actual earthquake motion time history, and send the data information of actual earthquake motion time history to the evaluation calculation module;

The data processing module is electrically connected to the model building module, and is used to process data of the building structures and send the processed data to the model building module;

The model construction module is electrically connected to the evaluation calculation module, and is used to construct a reliability model of the building structures according to the processed data;

The evaluation calculation module is used to input the data information of actual earthquake motion time history into the reliability model of the building structures to obtain and display evaluation results for intelligent resilience urban-rural areas.

The motion time history of earthquake motion is designed and used in this system to study influence on the reliability and safety of the building structures. Using the super-computing and storage capabilities of cloud computing, the reliability evaluation and health monitoring of complex building structure systems are realized, and are displayed through a visual operational platform that provides comprehensive information directly to those who need it.

The data information of actual earthquake motion time history includes information of earthquake motion acceleration and duration, the data information of actual earthquake motion time history is determined by an earthquake motion wave selection method, and is outputted in real time according to the actual occurrence of earthquake.

The data acquisition module has the following three functions, the first one is to collect seismic data; the second one is analysis of a time history response spectrum; and the third one is to build a seismic time history response spectrum database.

The first function is to collect all kinds of existing domestic and foreign seismic information (seismic waves), at the same time to monitor the local seismic data in real time, classify and organize them, and provide a data basis for subsequent processing;

The second function is to establish the response spectrum of earthquake motion time history based on the collected seismic data, through a response spectrum analysis method and a time history analysis method;

As for the response spectrum analysis: the seismic response spectrum is the functional relationship between maximum response of a building structure to some actual earthquake acceleration and the natural vibration characteristics of the system, that is, the response of the structure to vibration. From a formal point of view, the seismic response spectrum reflects the seismic motion characteristics of the whole process of the earthquake motion, which actually only reflects frequency characteristics of the most intense period of the earthquake ground motion, and cannot reflect the influence of the entire earthquake duration. The key to cause this deficiency is that the response spectrum does not change with time. In fact, the earthquake motion and the response of the stimulated system are varying with time. Therefore, a response spectrum including time factors is established by a time history analysis method, so that it can more comprehensively reflect the characteristics of earthquake ground motion, and its application prospects will be broader. As for the time history analysis: the response spectrum of earthquake motion time history is established by building the seismic response spectrum at each moment from the beginning to the end of the earthquake based on the input of the real seismic wave time and acceleration, in order to abbreviate the problem that the seismic response spectrum does not change with time. Thus, the response spectrum of the earthquake motion time history is obtained from the above two methods and the information data of the earthquake.

The third function is to build an information database of seismic time history for each type of the building structures, based on the accumulation of seismic data and the response spectrum analysis of the earthquake motion time history, while being combined with the local building structures and earthquake conditions, and to optimize and extract similar response spectrum of seismic time history, thereby providing a basis for the reliability evaluation of future building structures.

The data processing module decomposes the function and performance of the building structures based on the function-performance analysis method, and determines key characteristics and key performance indicators.

Firstly, preparation in advance: when analyzing the functional performance of the building structures, the preparation is carried out first, and the relevant information of the building structures is collected and sorted out. It includes: technical specifications, work contents of a scheme design, design patterns, information of similar products, performance tests that have been done, simulation, and the structure and data of various test items;

Secondly, functional analysis: in the functional analysis stage, the system definition of the building structures is finished at first, including clarifying the structural composition of the building structures, the functions of each part of the structures, environmental conditions and other information; and then, the basic flow for realizing the normal use function of the building structures is defined by calculating and analyzing the indicators of the building structures, the structural block diagram and functional block diagram of the building structures are established, and the functional logic relationship, data flow and other information are defined;

Thirdly, performance analysis: the structural performance analysis is carried out based on the results of the normal use function analysis of the building structures.

The structural performance is decomposed at first, and the importance is determined according to factors such as the severity of the performance out-of-tolerance consequences, the degree of user attention, etc., and the key characteristics and key performance parameters are determined in turn;

Then characteristic analysis of key performance parameters is carried out, and larger-the-better characteristic, smaller-the-better type characteristic, and nominal-the-type characteristic of the performance parameters are determined.

The larger-the-better performance parameters means: the performance parameters meeting the condition that when the larger the value of the performance parameter (in its own value space) is, the more favorable the realization of the function is;

The smaller-the-better performance parameters means: the performance parameters meeting the condition that when the smaller the value of the performance parameter (in its own value space) is, the more favorable the realization of the function is;

The nominal-the-type performance parameters means: the performance parameters meeting the condition that when the more approaching to some predetermined target value the value of the performance parameter is, the more favorable the realization of the function is;

Finally, the internal and external factors that affect the key performance indicators of the building structures are analyzed. The internal factors include: parameters such as structure, material, and process; and the external factors include: working stress, environmental stress and other factors. For the building structures that are the research object of this system, the factor that affects the key performance indicators of the building structure is generally meant to the earthquake.

The model building module is used to build a three-dimensional physical twin model of the building structures, including a frame structure, a frame-shear structure, a shear wall structure, a steel structure, a high-rise structure, a multi-layer structure, and a masonry structure.

A mathematical and structural model of loads and effects is established. The mechanism of common loads and effects of the building structures such as wind loads and earthquake effects is studied, the influence of loads and effects on prefabricated building structures and seismic reduction/isolation structure systems and products thereof is analyzed, and a mechanical model on loads and effects of seismic reduction/isolation structural systems and products thereof for prefabricated building structures is built.

### (1) Modeling is Prepared

The main components and their materials, dimensions, connection and the like of prefabricated building structures or seismic reduction/isolation structures are determined by preliminary analysis of the structures. Based on this, the units in the finite element analysis software applicable to each component are selected, and a material property model of the each component is further determined.

### (2) A Model is Built and is Divided Into Grids

In the finite element analysis software, the prefabricated building structures and the seismic reduction/isolation structure models are established, taking into comprehensive consideration of the structural characteristics and load and effect characteristics, the appropriate number of grids and the degree of grid density of each part are selected for grid division. When the accuracy is ensured to be sufficient, the calculation amount should be reduced as much as possible.

### (3) Loads and Boundary Conditions are Applied

According to the determined prefabricated building structures, seismic reduction/isolation structure system and the equivalent characterization method of product all life cycle load and effect, the loading type, loading method and loading magnitude of the finite element simulation analysis are determined, and other boundary conditions are specified according to the actual use environment of the structures.

### (4) Post-Processing

The solution in simulation is performed by using the finite element analysis software to obtain the stress, displacement and other analysis results of the finite element simulation analysis of the prefabricated building structures and the seismic reduction/isolation structures.

Specifically, the evaluation calculation module is used to receive the data information of actually occurring earthquake motion time history in real time, convert it into a finite element model of YJK calculation for cloud computing, output data of the safety displacement angles and weak layers of the structures, and map it to the urban-rural physical twin model through visual information, and then automatically generate evaluation results according to national regulations and emergency evaluation standards.

### (1) Establishing a Confident Reliability Evaluation Algorithm is Established

Based on the research on the confident reliability evaluation technology of building structures, a series of reliability evaluation operators for the building structures and reliability evaluation algorithms for complex structure systems composed of multiple components are established.

### (2) A Structural Health Monitoring Algorithm is Established

Based on the research on health monitoring technology of the building structures, a health monitoring platform of the building structures, including sensor optimization deployment algorithm, health state identification algorithm and safety and economic evaluation criterion algorithm of the structures based on confident reliability theory, is formed.

### (3) A Cloud Platform is Established

With the established reliability evaluation algorithm of the building structures and health monitoring algorithm of the structures as the calculation core, a cloud computing service system architecture is constructed and a fully functional intelligent resilience urban-rural evaluation cloud platform is developed.

The time history of earthquake motion designed and used in this system affects the reliability and safety of building structures and the influence thereof is studied. Using the super-computing and storage capabilities of cloud computing, the reliability evaluation and health monitoring of complex building structure systems are realized, and are displayed through a visually operational platform, thereby providing comprehensive information directly to those who need it.

### Second Embodiment

As shown in FIG. 2, an intelligent resilience urban-rural evaluation method is provided, which uses the intelligent resilience urban-rural evaluation system as described in first embodiment. The method includes the following steps:
S1. Building a 3D physical twin model of the building structures, including a frame structure, a frame-shear structure, a shear wall structure, a steel structure, a high-rise structure, a multi-storey structure, and a masonry structure;
S2. Inputting the data information of actual earthquake motion time history, outputting the displacement angles between layers of the building structure and the weak layers of the building structure in the calculation of YJK resilience dynamic motion time history, thereby obtaining evaluation indicators for the urban-rural resilience; and
S3. Superimposing the evaluation indicators for the urban-rural resilience with data from the urban-rural physical model, and transmitting them to the visualization system and the evaluation system, and finally generating three results that it can be used, discontinued, and suspended.

First of all, a three-dimensional physical twin model of the building structures and a digital information system are built, and the national standards are met;

Then, the data of actual earthquake motion time history is finished by the wave selection platform of earthquake motion time history, including 2,500 pieces of earthquake data that have occurred, and acceleration, velocity, and displacement values are outputted;

Finally, they are inputted into the YJK dynamic resilience calculation platform to output intelligent resilience urban-rural indicators, and resilience evaluation results are automatically generated.

The urban-rural physical model includes urban-rural built models and data for updating urban and rural areas.

The urban-rural built model information is determined by the urban-rural completed structure, and the data information for updating urban and rural area is updated in real time or manually according to the operation and maintenance situation.

Influence of the motion time history of earthquake designed and used in this method is studied on the reliability and safety of building structures. Using the super-computing and storage capabilities of cloud computing, the reliability evaluation and health monitoring of complex building structure systems can be realized. They can be displayed by a visual operational platform, thereby providing comprehensive information directly to those who need it.

The above description is only a preferred embodiment of the present invention, and is not intended to limit the present invention. Any modifications, equivalent replacements, improvements or the like made within the spirit and principles of the present invention shall be covered in the scope of the present invention.

What is claimed is:

1. An intelligent resilience urban-rural evaluation system, characterized in that: the system comprises a data acquisition module, a data processing module, a model building module and an evaluation calculation module;
wherein the data acquisition module is electrically connected to the evaluation calculation module, and is used to acquire data information of actual earthquake motion time history, and to send the data information of actual earthquake motion time history to the evaluation calculation module;
the data processing module is electrically connected to the model building module, and is used to process data of building structures and send the processed data to the model building module;
the model building module is electrically connected to the evaluation calculation module, and is used to build a reliability model of the building structures according to the processed data; and
the evaluation calculation module is used to input the data information of actual earthquake motion time history into the reliability model of the building structures to obtain and display evaluation results for intelligent resilience urban and rural areas.

2. The intelligent resilient urban-rural evaluation system according to claim 1, characterized in that the data information of actual earthquake motion time history comprises information of earthquake motion acceleration and duration, and the data information of actual earthquake motion time history is determined by an earthquake wave selection method, and is outputted in real time according to occurrence of actual earthquakes.

3. The intelligent resilient urban-rural evaluation system according to claim 1, characterized in that the data processing module decomposes functions and performances of the building structures based on a function-performance analysis method, and determines key characteristics and key performance indicators.

4. The intelligent resilient urban-rural evaluation system according to claim 1, characterized in that the model building module is used to build a three-dimensional physical twin model of the building structures which comprises a frame structure, a frame shear structure, a shear wall structure, a steel structure, a high-rise structure, a multi-storey structure, and a masonry structure.

5. The intelligent resilience urban-rural evaluation system according to claim 4, characterized in that the evaluation calculation module is used to receive in real time the data information of actual earthquake motion time history that is occurring, convert it into a finite element model of YJK calculation for cloud computing, and output data of safety displacement angles and weak layers of the structures, map it to the urban-rural physical twin model through visual information, and then automatically generate the evaluation results according to national regulations and emergency evaluation standards.

6. An intelligent resilience urban-rural evaluation method as used in the intelligent resilient urban-rural evaluation system according to claim 1, characterized in that: it comprises the following steps:
S1. building a three-dimensional physical twin model of the building structures which comprises a frame structure, a frame-shear structure, a shear wall structure, a steel structure, a high-rise structure, a multi-storey structure and a masonry structure;
S2. inputting the data information of actual earthquake motion time history, calculating and outputting the displacement angles between layers of the building structures and the weak layers of the building structure in YJK resilience dynamic motion time history, and obtain evaluation indicators of the urban-rural resilience; and
S3. superimposing the evaluation indicators of the urban-rural resilience with data from a urban-rural physical model, and transmitting them to a visualization system and an evaluation system, and finally generating three results that it can be used, discontinued, and suspended.

7. The intelligent resilience urban-rural evaluation method according to claim 6, characterized in that the urban-rural physical model comprises a urban-rural built model and data for updating urban and rural areas.

8. The intelligent resilience urban-rural evaluation method according to claim 6, characterized in that the data information of actual earthquake motion time history comprises information of earthquake motion acceleration and duration, and the data information of actual earthquake motion time history is determined by an earthquake wave selection method, and is outputted in real time according to occurrence of actual earthquakes.

9. The intelligent resilience urban-rural evaluation method according to claim 6, characterized in that the data processing module decomposes functions and performances of the building structures based on a function-performance analysis method, and determines key characteristics and key performance indicators.

10. The intelligent resilience urban-rural evaluation method according to claim 6, characterized in that the model building module is used to build a three-dimensional physical twin model of the building structures which comprises a frame structure, a frame shear structure, a shear wall structure, a steel structure, a high-rise structure, a multi-storey structure, and a masonry structure.

11. The intelligent resilience urban-rural evaluation method according to claim 10, characterized in that the evaluation calculation module is used to receive in real time the data information of actual earthquake motion time history that is occurring, convert it into a finite element model of YJK calculation for cloud computing, and output data of safety displacement angles and weak layers of the structures, map it to the urban-rural physical twin model through visual information, and then automatically generate the evaluation results according to national regulations and emergency evaluation standards.
